(19) United States
(12) Patent Application Publication
(10) Pub. No.: US 2025/0221174 A1
(43) Pub. Date: Jul. 3, 2025

(54) DISPLAY PANEL, METHOD OF MAKING DISPLAY PANEL, AND DISPLAY DEVICE

(71) Applicant: HKC CORPORATION LIMITED, Shenzhen (CN)

(72) Inventors: Yangling Tang, Shenzhen (CN); Xiufeng Zhou, Shenzhen (CN); Zhisheng Xie, Shenzhen (CN); Haijiang Yuan, Shenzhen (CN)

(21) Appl. No.: 19/000,059

(22) Filed: Dec. 23, 2024

(30) Foreign Application Priority Data
Dec. 27, 2023 (CN) 202311832335.5

(51) Int. Cl. H10K 59/122; H10K 59/12; H10K 59/80

(52) U.S. Cl. CPC H10K 59/122; H10K 59/1201; H10K 59/871

(57) ABSTRACT

A display panel includes a substrate, and a driving circuit layer, a pixel define layer, and a cover layer formed in sequence. The pixel define layer includes a pixel opening region and a pixel define portion around the pixel opening region. A side of the pixel define portion away from the substrate is opened with a partition groove surrounding the pixel opening region. The partition groove includes two side regions and an intermediate region between two side regions, and one of two side regions is close to the pixel opening region. The cover layer at least covers the side region on a side of the partition groove.

### CROSS-REFERENCE TO RELATED APPLICATIONS

The present application claims priority to Chinese Patent Application No. 202311832335.5, filed Dec. 27, 2023, the entire disclosure of which is hereby incorporated herein by reference.

### TECHNICAL FIELD

The present application belongs to the field of display, and particularly relates to a display panel, a method of making a display panel and a display device.

### BACKGROUND

Organic Light Emitting Diode (OLED) display panels become more and more important in the display field because of their thinness, high brightness, low power consumption, fast response, high clarity, and wide color gamut, etc.

A display panel includes a pixel define portion, an overhanging structure, a light-emitting layer, and a cathode formed sequentially, and the overhanging structure is used to isolate the light-emitting layer and to lap the cathode.

In related display panel designs, the overhanging structure needs to surround each sub-pixel by a circle, which results in a lower transmittance of the display panel and is not conducive to achieving functions such as fingerprint identification and infrared sensing.

### SUMMARY

There is provided a method of making a display panel, and a display device to improve the transmittance of the display panel according to embodiments of the present disclosure. The technical solution is as below.

According to a first aspect of embodiments of the present application, there is provided a display panel, including a substrate and a driving circuit layer, the driving circuit layer is formed on a side of the substrate. The display panel further includes:
a pixel define layer, formed on a side of the driving circuit layer away from the substrate, the pixel define layer includes a pixel opening region and a pixel define portion around the pixel opening region, and a side of the pixel define portion away from the substrate is opened with a partition groove surrounding the pixel opening region, the partition groove includes side regions close to the pixel opening region and an intermediate region between two side regions; and
a cover layer, formed on the side of the pixel define portion away from the substrate, wherein the cover layer at least covers the side region on a side of the partition groove.

According to a second aspect of embodiments of the present application, there is provided a method of making a display panel, which includes:
sequentially forming a driving circuit layer and a pixel define layer on a substrate;
patterning the pixel define layer to form a pixel opening region and a pixel define portion around the pixel opening region;
forming a cover material layer on a side of the pixel define portion away from the substrate; and
patterning the cover material layer to form a cover layer, and patterning the pixel define portion to form a partition groove;
the partition groove includes two side regions and an intermediate region between two side regions, and one of two side regions is close to the pixel opening region, and the cover layer at least covers the side region on a side of the partition groove.

Other features and advantages of the present application will become apparent through the following detailed description, or will be partially acquired through the practice of the present application.

It should be understood that the above general description and the detailed description that follows are exemplary and explanatory only and do not limit the present application.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. Obviously, the accompanying drawings in the following description are only some of the embodiments of the present application, and for those skilled in the art, other accompanying drawings may be obtained from these drawings without any creative labor.

FIG. 1 is a top view of the display panel in a first embodiment of the present application.

FIG. 2 is a cross sectional view of the display panel along line a-a in FIG. 1.

FIG. 3 is a cross sectional view of the display panel along line b-b in FIG. 1.

FIG. 4 is a cross sectional view of the display panel in a second embodiment of the present application.

FIG. 5 is a flowchart of a method of making the display panel in a third embodiment of the present application.

FIG. 6 is a view of patterning a cover material layer in the third embodiment of the present application.

FIG. 7 is a view of forming an overhanging structure in the third embodiment of the present application.

FIG. 8 is a view of a conductive material layer shielding the cover material layer in the third embodiment of the present application.

FIG. 9 is a view of removing the remaining conductive material layer after a partition groove is formed in the third embodiment of the present application.

FIG. 10 is a structural view of the display device in the fourth embodiment of the present application.

### DETAILED DESCRIPTION OF THE EMBODIMENTS

Embodiments will now be described more fully with reference to the accompanying drawings. However, the embodiments can be implemented in a variety of forms and should not be construed as limitation to the examples set forth herein; rather, the provision of these embodiments allows the present application to be more comprehensive and complete and conveys the idea of the embodiments in a comprehensive manner to those skilled in the art.

In addition, the described features, structures, or characteristics may be combined in one or more embodiments in any suitable manner. In the following description, many specific details are provided, thereby giving a full understanding of the embodiments of the present application. However, those skilled in the art will realize that it is possible to practice the technical solutions of the present application without one or more of the specific details, or that other methods, components, devices, steps, etc. may be employed. In other cases, the well-known methods, devices, implementations, or operations are not shown or described in detail to avoid blurring aspects of the present application.

The present application is described in further detail below in connection with the accompanying drawings and specific embodiments. It should be noted herein that the technical features involved in the various embodiments of the present application described below may be combined with each other, as long as they do not constitute a conflict with each other. The embodiments described below by reference to the accompanying drawings are exemplary and are intended to be used for explaining the present application and are not to be construed as a limitation of the present application.

### First Embodiment

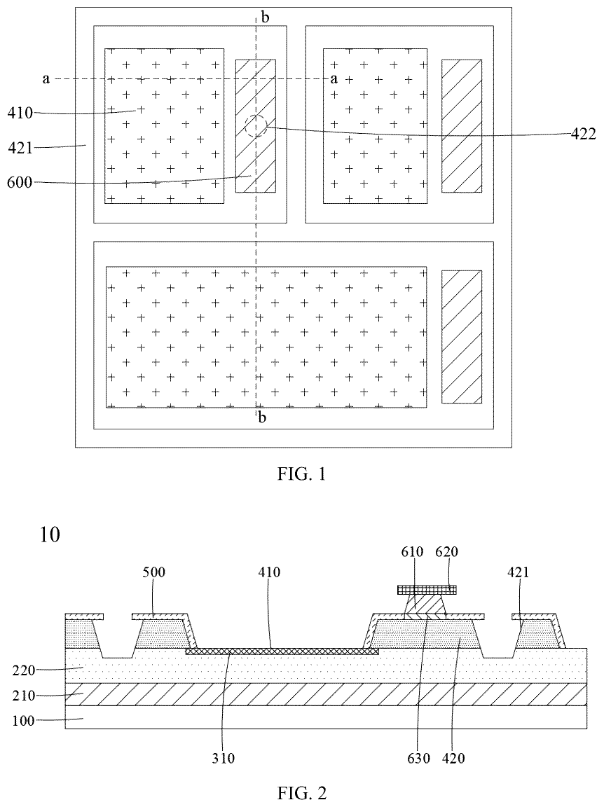

Referring to FIGS. 1 to 3, the display panel 10 in this embodiment includes a substrate 100, a driving circuit layer 210, a flat layer 220, an anode layer 300, a pixel define layer 400, and a cover layer 500.

The driving circuit layer 210 is formed on a side of the substrate 100. The flat layer 220 is formed on a side of the driving circuit layer 210 away from the substrate 100, and the anode layer 300 is formed on a side of the flat layer 220 away from the substrate 100. The anode layer 300 includes a plurality of anodes 310, each of which is passed through the flat layer 220 to connect to the driving circuit layer 210.

A pixel define layer 400 is formed on the side of the flat layer 220 away from the substrate 100, and the pixel define layer 400 includes a pixel opening region 410 and a pixel define portion 420 around the pixel opening region 410. The pixel define portion 420 covers an edge region of each anode 310, and the pixel opening region 410 exposes a central region of each anode 310.

A side of the pixel define portion 420 away from the substrate 100 is opened with a partition groove 421 surrounding the pixel opening region 410, and the partition groove 421 includes two side regions 4211 and an intermediate region 4212 between two side regions 4211, and one of two side regions 4211 is close to the pixel opening region 410. A cover layer 500 is formed on the side of the pixel define portion 420 away from the substrate 100, and the cover layer 500 at least covers the side region 4211 on the side of the partition groove 421. In one embodiment, the cover layer 500 at least covers the side regions 4211 on two sides of the partition groove 421. The flat layer 220, the pixel define layer 400, and the cover layer 500 are all light-transmitting structural layers.

In addition, the display panel 10 may also include a hole injection layer, a hole transport layer, a light-emitting layer, an electron transport layer, an electron injection layer, and a cathode layer not shown. The hole injection layer, the hole transport layer, the light-emitting layer, the electron transport layer, the electron injection layer, and the cathode layer are formed in sequence and located at least in the pixel opening region 410 to form an OLED sub-pixel. The cathode layer of each OLED sub-pixel is connected to the driving circuit layer 210, and the hole injection layer and the hole transport layer of at least adjacent OLED sub-pixels are separated.

In some display panel designs, a side of the pixel define portion 420 away from the substrate 100 is provided with an eave structure, and the eave structure includes a conductor layer and an eave layer. The conductor layer is provided on the side of the pixel define portion 420 away from the substrate 100, and the eave layer is provided on a side of the conductor layer away from the substrate 100. The hole injection layer and the hole transport layer, etc. of the adjacent OLED sub-pixels are separated by the eave structure, and the cathode layers of the adjacent OLED sub-pixels are connected by the conductor layer, and then directly or indirectly connected to the driving circuit layer 210. The eave structure needs to surround each sub-pixel by a circle, and the eave structure is opaque or has a low transmittance, which results in a lower transmittance of the display panel, and is not conducive to achieving functions such as fingerprint identification and infrared sensing.

In this embodiment, a display panel 10 includes a substrate 100, and a driving circuit layer 210, a pixel define layer 400, and a cover layer 500 formed in sequence. The pixel define layer 400 is formed on a side of the driving circuit layer 210 away from the substrate 100, the pixel define layer 400 includes a pixel opening region 410 and a pixel define portion 420 around the pixel opening region 410. A side of the pixel define portion 420 away from the substrate 100 is opened with a partition groove 421 surrounding the pixel opening region 410. The partition groove 421 includes a side region 4211 close to the pixel opening region 410 and an intermediate region 4212 between two side regions 4211. The cover layer 500 is formed on the side of the pixel define portion 420 away from the substrate 100, and the cover layer 500 at least covers the side region 4211 on a side of the partition groove 421. The partition groove 421 and the cover layer 500 are used to partition adjacent OLED sub-pixels, which reduces the shading area of the eave structure, and improves the transmittance of the display panel as compared to partitioning adjacent OLED sub-pixels by an eave structure.

Referring to FIGS. 1 to 3, the display panel 10 further includes an overhanging structure 600, the overhanging structure 600 is formed on the side of the pixel define portion 420 away from the substrate 100. The overhanging structure 600 is located on a side of the pixel opening region 410 and is located on a side of the partition groove 421 close to the pixel opening region 410. The overhanging structure 600 includes a conductor portion 610 and an eave portion 620. The conductor portion 610 is formed on the side of the pixel define portion 420 away from the substrate 100. The eave portion 620 is formed on the side of the conductor portion 610 away from the substrate 100. A positive projection of the conductor portion 610 on the pixel define portion 420 is located within a positive projection of the eave portion 620 on the pixel define portion 420. The conductor portion 610 is used to connect to the cathode layer and the driving circuit layer 210.

The overhanging structure 600 is formed on a side of the pixel opening region 410, and the cover layer 500 between the overhanging structure 600 and the partition groove 421 can be omitted. In addition, the conductor portion 610 of the overhanging structure 600 may connect the cathode layer of each OLED sub-pixel to the driving circuit layer 210, which may reduce impedance compared to the scheme in which the cathode layers of adjacent OLED sub-pixels are connected by the conductor layer, and then connected to the driving circuit layer 210.

Referring to FIGS. 1 to 3, the overhanging structure 600 further includes a first conductive connection portion 630 formed between the conductor portion 610 and the pixel define portion 420. The first conductive connection portion 630 may be a non-conductive structural layer, and the conductor portion 610 is passed through the first conductive connection portion 630 to connect to the driving circuit layer 210.

The first conductive connection portion 630 improves connection adhesion between the conductor portion 610 and the pixel define portion 420, thereby improving the yield of the display panel 10.

The first conductive connection portion 630 may be a non-conductive structural layer, but without limitation herein. The first conductive connection portion 630 may also be a conductive structural layer, which is specifically determined as actual. When the first conductive connection portion 630 is a conductive structural layer, the conductor portion 610 is passed through the first conductive connection portion 630 to connect to the driving circuit layer 210 or the conductor portion 610 is connected to the driving circuit layer 210 via the first conductive connection portion 630.

Referring to FIGS. 1 to 3, the anode layer 300 further includes a second conductive connection portion 320, the pixel define portion 420 has a first via hole 422, and the conductor portion 610 is passed through the first via hole 422 of the pixel define portion 420 to connect to the second conductive connection portion 320. The flat layer 220 has a second via hole 221 and a third via hole 222, and the second conductive connection portion 320 is passed through the second via hole 221 of the flat layer 220 to connect to the driving circuit layer 210. The anode 310 is passed through the third via hole 222 of the flat layer 220 to connect to the driving circuit layer 210.

The second conductive connection portion 320 is passed through the second via hole 221 of the flat layer 220 to connect to the driving circuit layer 210, and the conductor portion 610 is passed through the first via hole 422 of the pixel define portion 420 to connect to the second conductive connection portion 320, which may avoid deep-hole etching at the pixel define portion 420 and the flat layer 220 for the connection of the conductor portion 610 to the driving circuit layer 210, and the second conductive connection portion 320 and the anode 310 may be fabricated in the same process, thereby simplifying the fabrication process of the display panel 10 and reducing the fabrication cost of the display panel 10.

It is to be noted that the conductor portion 610 may be indirectly connected to the driving circuit layer 210 via the second conductive connection portion 320, but is not limited thereto, and the conductor portion 610 may also be passed through the pixel define portion 420 and the flat layer 220 to directly connect to the driving circuit layer 210, which is specifically determined as actual.

In some embodiments, the cover layer 500 is a non-conductive structural layer, and the cover layer 500 may include a silicone oxide, a silicone nitrogen compound, or a silicone oxynitride compound, etc. The cover layer 500 at least covers two side regions 4211 of the partition groove 421, and the cover layer 500 between the overhanging structure 600 and the partition groove 421 may be omitted when the cathode layer and the driving circuit layer 210 are connected via the conductor portion 610 of the overhanging structure 600.

The cover layer 500 is a non-conductive structural layer, which reduces the risk of the hole injection layer and the hole transport layer, etc. of adjacent OLED sub-pixels being connected via the cover layer 500.

Referring to FIGS. 1 to 3, the cover layer 500 further covers the side of the pixel define portion 420 away from the substrate 100 and the sidewall of the pixel opening region 410 formed by the pixel define portion 420.

The cover layer 500 covers the side of the pixel define portion 420 away from the substrate 100 and the sidewall of the pixel opening region 410 formed by the pixel define portion 420, which can prevent the pixel define portion 420 from being damaged in subsequent processes.

Referring to FIGS. 1 to 3, the partition groove 421 is extended into the flat layer 220.

Since the partition groove 421 is extended into the flat layer 220, the depth of the partition groove 421 is increased, which may improve the effect of the partition groove 421 and the cover layer 500 in partitioning adjacent OLED sub-pixels.

### Second Embodiment

The second Embodiment differs from the first embodiment in that the cover layer 500 is different.

Referring to FIG. 4, the cover layer 500 is a conductive structural layer, and the cover layer 500 covers a side region 4211 on the side of the partition groove 421 away from the conductor portion 610. The display panel 10 also includes an overhanging structure 600, and the overhanging structure 600 is formed on the side of the pixel define portion 420 away from the substrate 100 and is located on the side of the partition groove 421 close to the pixel opening region 410. For the side region 4211 on the side of the partition groove 421 close to the conductor portion 610: a portion of the cover layer 500 between the overhanging structure 600 and the partition groove 421 may be omitted, and the cover layer 500 is provided between the pixel opening region 410 and the partition groove 421.

For the side region 4211 on the side of the partition groove 421 close to the conductor portion 610: a portion of the cover layer 500 between the overhanging structure 600 and the partition groove 421 is omitted, which can reduce the risk of the hole injection layer and the hole transport layer, etc. of adjacent OLED sub-pixels being connected via the cover layer 500.

Referring to FIG. 4, the overhanging structure 600 further includes a first conductive connection portion 630 provided between the conductor portion 610 and the pixel define portion 420. The cover layer 500 and the first conductive connection portion 630 are provided in the same layer. Both the cover layer 500 and the first conductive connection portion 630 may include indium zinc oxide (IZO).

The first conductive connection portion 630 may improve connection adhesion between the conductor portion 610 and the pixel define portion 420, thereby improving a yield of the display panel 10. The cover layer 500 and the first conductive connection portion 630 are provided in the same layer, thereby simplifying the fabrication process of the display panel 10 and reducing the fabrication cost of the display panel 10.

### Third Embodiment

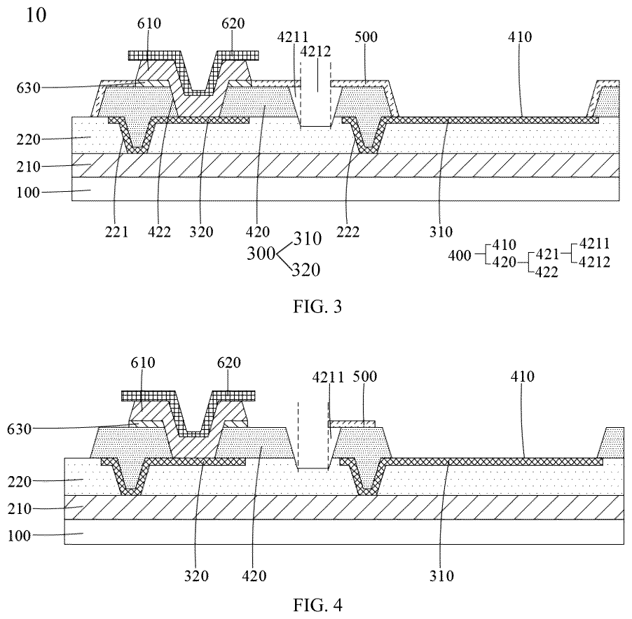

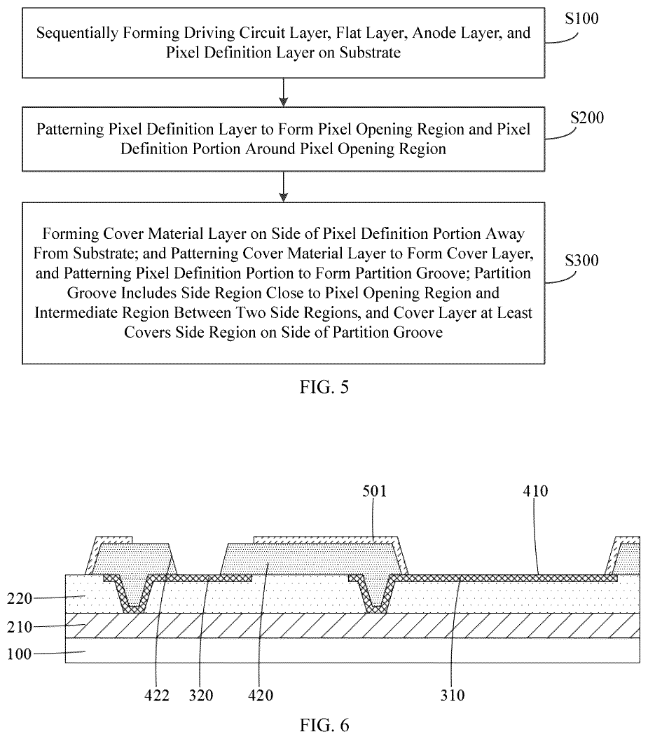

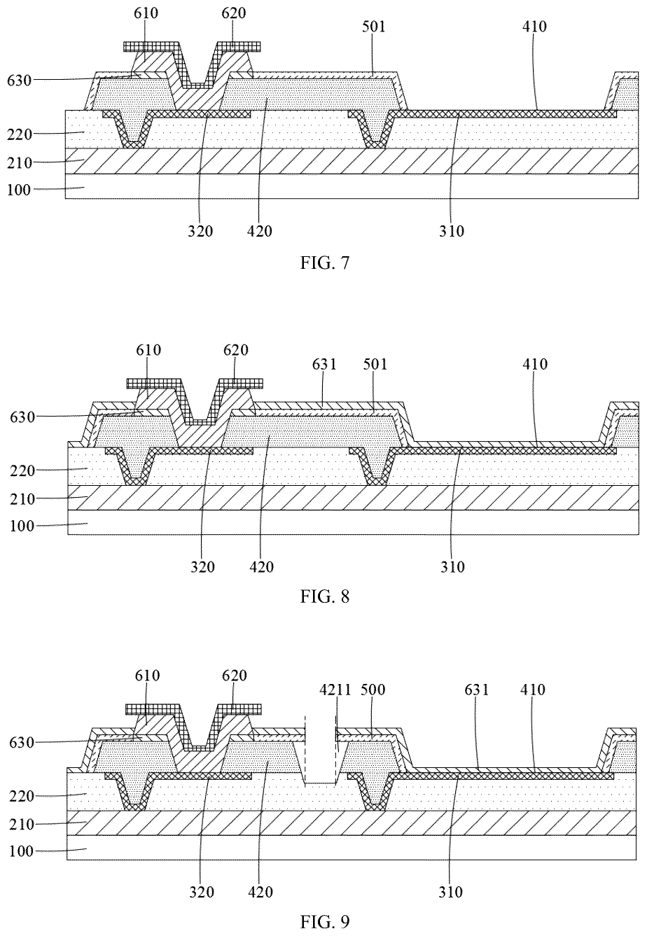

The present embodiment also provides a method of making a display panel for making the display panel 10 disclosed in the first embodiment and the second embodiment. Referring to FIG. 3 and FIGS. 5 to 7, the method of making the display panel in the present embodiment includes:

S100: sequentially forming a driving circuit layer 210, a flat layer 220, an anode layer 300, and a pixel define layer 400 on the substrate 100.

The anode layer 300 includes an anode 310 and a second conductive connection portion 320. After the flat layer 220 is formed, a second via hole 221 and a third via hole 222 passing through the flat layer 220 are formed on the flat layer 220, the anode 310 is passed through the third via hole 222 to connect to the driving circuit layer 210, and the second conductive connection portion 320 is passed through the second via hole 221 to connect to the driving circuit layer 210.

S200: patterning the pixel define layer 400 to form a pixel opening region 410 and a pixel define portion 420 around the pixel opening region 410.

The pixel define portion 420 covers an edge region of the anode 310 and the pixel opening region 410 exposes a central region of the anode 310.

S300: forming a cover material layer 501 on a side of the pixel define portion 420 away from the substrate 100; and patterning the cover material layer 501 to form a cover layer 500, and patterning the pixel define portion 420 to form a partition groove 421; the partition groove includes two side regions 4211 and an intermediate region 4212 between two side regions 4211, and one of two side regions 4211 is close to the pixel opening region 410, and the cover layer 500 at least covers the side region 4211 on a side of the partition groove 421.

When the pixel define portion 420 is patterned to form the partition groove 421, the partition groove 421 may be located in the pixel define layer 400, and passed through the pixel define layer 400, or extended into the flat layer 220.

It should be noted that the display panel 10 also includes structural layers, not shown, such as a light-emitting layer, a cathode layer, and an encapsulation layer. The light-emitting layer, the cathode layer, and the encapsulation layer are formed sequentially and at least in the pixel opening region 410. The encapsulation layer may be an entire film layer, but is not limited herein, and the encapsulation layer may be separated by the partition groove 421 and the cover layer 500, which is specifically determined as actual.

The method of making the display panel includes: sequentially forming a driving circuit layer 210, a flat layer 220, an anode layer 300, and a pixel define layer 400 on the substrate 100; patterning the pixel define layer 400 to form a pixel opening region 410 and a pixel define portion 420 around the pixel opening region 410; forming a cover material layer 501 on a side of the pixel define portion 420 away from the substrate 100; and patterning the cover material layer 501 to form a cover layer 500, and patterning the pixel define portion 420 to form a partition groove 421; the partition groove includes a side region 4211 close to the pixel opening region 410 and an intermediate region 4212 between two side regions 4211, and the cover layer 500 at least covers the side region 4211 on a side of the partition groove 421. The partition groove 421 and the cover layer 500 are used to partition adjacent OLED sub-pixels, which reduces the shading area of the eave structure and improves the transmittance of the display panel 10 compared to partitioning adjacent OLED sub-pixels through the eave structure.

Referring to FIG. 3 and FIGS. 5 to 7, the method of making the display panel includes:
patterning the cover material layer 501 and the pixel define portion 420 after the cover material layer 501 is formed and before the partition groove 421 is formed; and forming a first via hole 422 in the pixel define portion 420, and forming an overhanging structure 600 on the side of the pixel define portion 420 away from the substrate 100; the overhanging structure 600 includes a conductor portion 610 and an eave portion 620 on a side of the conductor portion 610 away from the substrate 100, and the conductor portion 610 is passed through the first via hole 422 to connect to the driving circuit layer 210.

When the display panel 10 is fabricated, the overhanging structure 600 is first formed on the pixel define portion 420, and then the cover material layer 501 and the pixel define portion 420 are etched to form the partition groove 421 and the cover layer 500, which can avoid damage to the cover layer 500 during making the overhanging structure 600, thereby avoiding affecting the effect of the partition groove 421 and the cover layer 500 in partitioning the adjacent OLED sub-pixels.

Referring to FIGS. 3, 6, 8, and 9, the overhanging structure 600 further includes a first conductive connection portion 630 provided between the conductor portion 610 and the pixel define portion 420. The method of making the display panel includes:
after the cover material layer 501 is formed, patterning the cover material layer 501 including a region for opening a first via hole 422 in the pixel define portion 420 and a pixel opening region 410, then forming a conductive material layer 631 on the side of the pixel define portion 420 away from the substrate 100, and then etching the conductive material layer 631 and the pixel define portion 420 to form the first via hole 422, and then forming the overhanging structure 600, the cover layer 500, and the partition groove 421, and finally removing the remaining conductive material layer 631 beyond a range covered by the conductor portion 610 to form the first conductive connection portion 630.

In the process of forming the partition groove 421, the conductive material layer 631 can protect the cover layer 500, which can avoid damage to the cover layer 500, thereby avoiding affecting the effect of the partition groove 421 and the cover layer 500 in partitioning the adjacent OLED sub-pixels.

### Fourth Embodiment

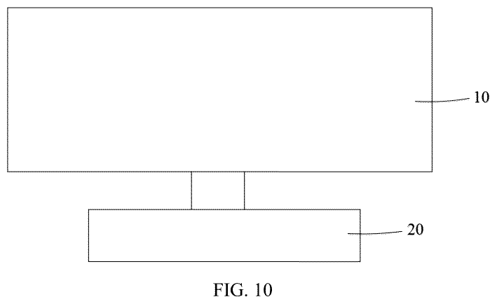

This embodiment also provides a display device, as shown in FIG. 10. The display device includes a display panel 10 and a main board 20. The main board 20 is connected to the display panel 10, which includes the display panel 10 disclosed in the first embodiment and second embodiment.

The display device includes the display panel 10, the display panel 10 includes a substrate 100, and a driving circuit layer 210, a pixel define layer 400, and a cover layer 500 formed in sequence. The pixel define layer 400 is formed on a side of the driving circuit layer 210 away from the substrate 100. The pixel define layer 400 includes a pixel opening region 410 and a pixel define portion 420 around the pixel opening region 410. A side of the pixel define portion 420 away from the substrate 100 is opened with a partition groove 421 surrounding the pixel opening region 410, the partition groove 421 includes two side regions 4211 and an intermediate region 4212 between two side regions 4211, and one of two side regions 4211 is close to the pixel opening region 410, and the cover layer 500 is formed on the side of the pixel define portion 420 away from the substrate 100, and the cover layer 500 at least covers the side region 4211 on a side of the partition groove 421. The partition groove 421 and the cover layer 500 are used to partition adjacent OLED sub-pixels, which reduces the shading area of the eave structure and improves the transmittance of the display panel 10 as compared to partitioning adjacent OLED sub-pixels by an eave structure.

The terms “first”, “second”, etc. are used for descriptive purposes only, and are not to be understood as indicating or implying relative importance or implicitly specifying the number of technical features indicated. Accordingly, a feature defined with “first”, “second”, etc. may expressly or implicitly include one or more such features. In the description of the present application, “more than one” means two or more, unless otherwise expressly and specifically limited.

In this application, unless otherwise expressly specified and limited, the terms “assembly”, “connection”, etc. are to be understood in a broad sense, for example, they may be fixed, removable or integral, or may be mechanically connected or electrically connected, or may be a direct connection or an indirect connection through an intermediate medium, a connection within two elements or an interaction between two elements. For those skilled in the art, the specific meanings of the above terms in the present application may be understood based on the actual situation.

In the description of the present specification, the description with reference to the terms “some embodiments”, “exemplarily”, etc. means that specific features, structures, materials, or characteristics described in conjunction with the embodiments or examples are included in at least one embodiment or example of the present application. In this specification, schematic expressions of the above terms do not necessarily refer to the same embodiment or example. Moreover, the specific features, structures, materials, or characteristics described may be combined in a suitable manner in any one or more of the embodiments or examples. Moreover, without contradicting each other, those skilled in the art may combine different embodiments or examples and features of different embodiments or examples described in this specification.

Although the embodiments of the present application have been shown and described above, it is understood that the above embodiments are exemplary and cannot be construed as a limitation of the present application, and that those skilled in the art may make changes, modifications, substitutions, and variations of the above embodiments within the scope of the present application, and therefore any changes or modifications made in accordance with the claims and the specification of the present application shall fall within the scope of the present application.

What is claimed is:

1. A display panel, comprising a substrate and a driving circuit layer, wherein the driving circuit layer is formed on a side of the substrate, wherein the display panel further comprises:
a pixel define layer, formed on a side of the driving circuit layer away from the substrate, wherein the pixel define layer comprises a pixel opening region and a pixel define portion around the pixel opening region, and a side of the pixel define portion away from the substrate is opened with a partition groove surrounding the pixel opening region, wherein the partition groove comprises two side regions and an intermediate region between the two side regions, and one of the two side regions is close to the pixel opening region; and
a cover layer, formed on the side of the pixel define portion away from the substrate, wherein the cover layer at least covers a side region on a side of the partition groove.

2. The display panel according to claim 1, further comprising an overhanging structure, wherein the overhanging structure is formed on the side of the pixel define portion away from the substrate, and the overhanging structure is located on a side of the pixel opening region, and located on a side of the partition groove close to the pixel opening region;
wherein the overhanging structure comprises a conductor portion and an eave portion on a side of the conductor portion away from the substrate, and the conductor portion is configured for connecting a cathode layer and the driving circuit layer.

3. The display panel according to claim 2, wherein the cover layer is a conductive structural layer, and the cover layer covers the side region on the side of the partition groove away from the conductor portion; or
the cover layer is a non-conductive structural layer, and the cover layer at least covers the two side regions of the partition groove.

4. The display panel according to claim 3, wherein when the cover layer is the conductive structural layer, the overhanging structure further comprises a first conductive connection portion provided between the conductor portion and the pixel define portion, and the cover layer and the first conductive connection portion are provided in a same layer.

5. The display panel according to claim 3, wherein the cover layer is the non-conductive structural layer, and the cover layer further covers the side of the pixel define portion away from the substrate and a sidewall of the pixel opening region formed by the pixel define portion.

6. The display panel according to claim 2, further comprising a flat layer and an anode layer, wherein the flat layer is formed on the side of the driving circuit layer away from the substrate, and the anode layer is formed on a side of the flat layer away from the substrate;
wherein the anode layer comprises a plurality of anodes spaced apart, and each anode is passed through the flat layer to connect to the driving circuit layer, and the pixel define portion covers an edge region of each anode, and the pixel opening region exposes a central region of each anode; and
wherein the anode layer further comprises a second conductive connection portion, the conductor portion is passed through the pixel define portion to connect to the second conductive connection portion, and the second conductive connection portion is passed through the flat layer to connect to the driving circuit layer.

7. The display panel according to claim 1, further comprising a flat layer and an anode layer, wherein the flat layer is formed on the side of the driving circuit layer away from the substrate, and the anode layer is formed on a side of the flat layer away from the substrate;
wherein the anode layer comprises a plurality of anodes spaced apart, and each anode is passed through the flat layer to connect to the driving circuit layer, and the pixel define portion covers an edge region of each anode, and the pixel opening region exposes a central region of each anode, and the partition groove is extended into the flat layer.

8. The display panel according to claim 7, wherein the flat layer, the pixel define layer and the cover layer are light-transmitting structural layers.

9. The display panel according to claim 1, wherein the display panel further comprises a hole injection layer, a hole transport layer, a light-emitting layer, an electron transport layer, an electron injection layer, and a cathode layer not shown; and the hole injection layer, the hole transport layer, the light-emitting layer, the electron transport layer, the electron injection layer, and the cathode layer are formed in sequence and located at least in the pixel opening region to form an Organic Light Emitting Diode (OLED) sub-pixel; and
the cathode layer of each OLED sub-pixel is connected to the driving circuit layer, and the hole injection layer and the hole transport layer of at least adjacent OLED sub-pixels are separated.

10. A method of making a display panel, comprising:
sequentially forming a driving circuit layer and a pixel define layer on a substrate;
patterning the pixel define layer to form a pixel opening region and a pixel define portion around the pixel opening region;
forming a cover material layer on a side of the pixel define portion away from the substrate; and
patterning the cover material layer to form a cover layer, and patterning the pixel define portion to form a partition groove;
wherein the partition groove comprises two side regions and an intermediate region between the two side regions, and one of the two side regions is close to the pixel opening region, and the cover layer at least covers a side region on a side of the partition groove.

11. The method of making the display panel according to claim 10, further comprising:
patterning the cover material layer and the pixel define portion after the cover material layer is formed and before the partition groove is formed; and
forming a first via hole in the pixel define portion, and forming an overhanging structure on the side of the pixel define portion away from the substrate;
wherein the overhanging structure comprises a conductor portion and an eave portion on a side of the conductor portion away from the substrate, and the conductor portion is passed through the first via hole to connect to the driving circuit layer.

12. A display device, comprising a display panel, and a main board connected to the display panel;
wherein the display panel comprises a substrate and a driving circuit layer, wherein the driving circuit layer is formed on a side of the substrate, wherein the display panel further comprises:
a pixel define layer, formed on a side of the driving circuit layer away from the substrate, wherein the pixel define layer comprises a pixel opening region and a pixel define portion around the pixel opening region, and a side of the pixel define portion away from the substrate is opened with a partition groove surrounding the pixel opening region, wherein the partition groove comprises two side regions close to the pixel opening region and an intermediate region between the two side regions; and
a cover layer, formed on the side of the pixel define portion away from the substrate, wherein the cover layer at least covers a side region on a side of the partition groove.

13. The display device according to claim 12, further comprising an overhanging structure, wherein the overhanging structure is formed on the side of the pixel define portion away from the substrate, and the overhanging structure is located on a side of the pixel opening region, and located on a side of the partition groove close to the pixel opening region;
wherein the overhanging structure comprises a conductor portion and an eave portion on a side of the conductor portion away from the substrate, and the conductor portion is configured for connecting a cathode layer and the driving circuit layer.

14. The display device according to claim 13, wherein the cover layer is a conductive structural layer, and the cover layer covers the side region on the side of the partition groove away from the conductor portion; or
the cover layer is a non-conductive structural layer, and the cover layer at least covers the two side regions of the partition groove.

15. The display device according to claim 14, wherein when the cover layer is the conductive structural layer, the overhanging structure further comprises a first conductive connection portion provided between the conductor portion and the pixel define portion, and the cover layer and the first conductive connection portion are provided in a same layer.

16. The display device according to claim 14, wherein the cover layer is the non-conductive structural layer, and the cover layer further covers the side of the pixel define portion away from the substrate and a sidewall of the pixel opening region formed by the pixel define portion.

17. The display device according to claim 13, further comprising a flat layer and an anode layer, wherein the flat layer is formed on the side of the driving circuit layer away from the substrate, and the anode layer is formed on a side of the flat layer away from the substrate;
wherein the anode layer comprises a plurality of anodes spaced apart, and each anode is passed through the flat layer to connect to the driving circuit layer, and the pixel define portion covers an edge region of each anode, and the pixel opening region exposes a central region of each anode; and
wherein the anode layer further comprises a second conductive connection portion, the conductor portion is passed through the pixel define portion to connect to the second conductive connection portion, and the second conductive connection portion is passed through the flat layer to connect to the driving circuit layer.

18. The display device according to claim 12, further comprising a flat layer and an anode layer, wherein the flat layer is formed on the side of the driving circuit layer away from the substrate, and the anode layer is formed on a side of the flat layer away from the substrate;
wherein the anode layer comprises a plurality of anodes spaced apart, and each anode is passed through the flat layer to connect to the driving circuit layer, and the pixel define portion covers an edge region of each anode, and the pixel opening region exposes a central region of each anode, and the partition groove is extended into the flat layer.

19. The display device according to claim 18, wherein the flat layer, the pixel define layer and the cover layer are light-transmitting structural layers.

20. The display device according to claim 12, wherein the display panel further comprises a hole injection layer, a hole transport layer, a light-emitting layer, an electron transport layer, an electron injection layer, and a cathode layer not shown; and the hole injection layer, the hole transport layer, the light-emitting layer, the electron transport layer, the electron injection layer, and the cathode layer are formed in sequence and located at least in the pixel opening region to form an Organic Light Emitting Diode (OLED) sub-pixel; and
the cathode layer of each OLED sub-pixel is connected to the driving circuit layer, and the hole injection layer and the hole transport layer of at least adjacent OLED sub-pixels are separated.
